(19) United States
(12) Patent Application Publication
(10) Pub. No.: US 2007/0188046 A1
(43) Pub. Date: Aug. 16, 2007

(54) Energy recovery device

(75) Inventors: Jean-Jacques Chaillout, St Etienne De Crossey (FR); Ghislain Despesse, Grenoble (FR); Thomas Jager, Grenoble (FR); Andrea Vassilev, Grenoble (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: Commissariat A L'Energie Atomique, Paris (FR)

(21) Appl. No.: 11/630,995

(22) PCT Filed: Jul. 5, 2005
(86) PCT No.: PCT/FR05/50542

§ 371 Date: Dec. 28, 2006

(30) Foreign Application Priority Data
Jun. 6, 2004 (FR) 0451454

(51) Int. Cl. H01L 41/00

(52) U.S. Cl. 310/311

(57) ABSTRACT

A device for recovering mechanical energy from a mobile support and/or from a fluid in movement. The device includes a part fixed to the support or fluid, and a mobile part in suspension. The fixed part is of lower mass than the mobile part. The mobile part includes a case of the device.

### TECHNICAL AREA

This present invention concerns systems that are capable of recovering the energy coming from movements in their environment (vibration, impacts, flows, etc.) and based on the principle of a mass in suspension performing relative movements in relation to this environment.

### PRIOR ART

The principle of energy generation by relative movement between two devices is known from document EP-A-0 008 237 for example. This was applied for the recovery of energy from a mobile system, in document GB-A-2 311 171 for example, in which a heavy part, generally external, is fixed rigidly (screwing, glueing, etc.) to a support in movement, and a mobile light part, generally internal, is linked to the fixed part by a flexible link. The mobile part, in suspension, by virtue of its inertia, effects a relative movement in relation to the fixed part, and therefore to the support; a converter converts the recovered mechanical energy into the wanted energy form, which can be anything (electrical, thermal, mechanical, etc.), using any type of conversion. As an example, in the case of electrical converters, the principle of conversion can be electromagnetic, capacitive, electrostatic, piezo-electric, or other.

FIG. 1 illustrates a particular example concerning the conversion of mechanical energy into electrical energy by the capacitive principle. The device 1 comprises a case 2 fixed to a support 3 which is subjected to vibration. Inside the case 2 is located an energy conversion system consisting of two electrodes 4, 5. The first electrode 4 is attached to the case 2 in a rigid way, and the second electrode 5 is attached to the case in a flexible way, by means of a spring 6. The relative movement of the two electrodes 4, 5 changes the value of the capacitance and by means of a connector 7, is able to generate electrical energy in the operating system 8.

However, whatever the nature and the performance of the energy converter, since the mobile part of the current devices is generally included in the fixed part, they are unable to recover energy coming from movements other than those of a support to which they are connected, so that, for example, the movement of a surrounding fluid cannot be converted into energy.

Moreover, these known devices have very low recovery efficiencies. It has been observed that in fact the energy recoverable by this type of device is limited by the mass of the mobile part.

In fact, by way of an example, considering the context of an electrical converter using the capacitive principle of figure 1, the equation of the movement take the following form:
m.z″+f(bₑ, bₘ, z′, z″)+kₘ.z=−m.a(t); in which:
m: mass of the mobile part 5,
z: relative movement between the mobile part and the vibrating support,
a(t): acceleration of the vibrating support,
kₘ: stiffness of the return spring 6,
bₑ: electrical damping of the electrical force between the electrodes 4 and 5,
bₘ: viscous mechanical damping (if any).

Secondly, the recoverable energy corresponds to the kinetic energy of the mass of the mobile part according to the expression:

$${E}_{recup} = \frac{1}{2} m \cdot {z}^{′2} .$$

The recovery of energy in the downstream system therefore takes the form of a mechanical damping of electrical origin (coefficient bₑ). Due to the fact that, for the known systems, the mass of the mobile part is lighter than that of the fixed part, their massic or volumic energies are not very competitive.

### PRESENTATION OF THE INVENTION

The invention proposes to overcome these drawbacks of the existing devices and, amongst other advantages, to recover more energy using a suspension device, in particular one of constant volume.

From one of its aspects, the invention concerns a device that comprises two parts which are linked together and movable in relation to each other, with one of the parts being equipped with means for being connected in a rigid way to a support. The part equipped with the rigid connection means is of lower mass than the other part of the device. Thus the energy recovered, directly associated with the mass of the mobile part, is increased.

The mobile part is composed of a case in which the fixed part is located. A rigid link is able to pass through the case in order to fix the device to a support. Sealing resources can be provided at the point of penetration of this rigid link. In particular in this case, the part in movement is also sensitive to movements other than those of the support.

Advantageously, the mobile part comprises elements, such as conversion systems, energy storage systems, etc. other than the case, which allows the weight difference between the two parts to be increased still further. In particular, an antenna can be present on the outside of the case.

The device according to the invention can be designed with any type of conversion: mechanical/mechanical, mechanical/thermal, mechanical/electrical using the piezoelectric principle, mechanical/electrical using the capacitive principle, and so on.

According to the invention, the device can be connected to a mobile support, which is subjected to vibrations for example. It can also be used in an environment in which the fluid surrounding it is in motion, when the mechanical energy of these movements can also be recovered and converted.

### BRIEF DESCRIPTION OF THE DRAWINGS

The attached figures will enable the invention to be understood more clearly, but are provided only as a guide, and they restrict the invention in no way whatever.

FIG. 1, already described, illustrates a known device for the recovery of mechanical energy using the capacitive principle.

FIGS. 2A and 2B show the principles of operation of energy recovery devices, respectively according to prior art and according to the invention.

FIGS. 3A-3D represent diverse applications of the principle of recovery according to the invention.

FIG. 4 illustrates the use of a device according to one method of implementation of the invention in an environment of fluid in movement.

### DETAILED PRESENTATION OF PARTICULAR METHODS OF EMBODIMENTS

As illustrated in FIG. 2A, the principle on which the known energy recovery devices 1 is based is the attachment of one part 2, 4, 8 to a mobile support 3, and the installation of a flexible link 6 between this “fixed” part 2 and another element 5, which is therefore mobile in relation to it and to the support. The element in suspension 5 is usually composed of a counterweight or of a ballast, while the fixed part often comprises a case 2 as well as energy transfer systems 4, 8. In the conventional systems 1, the fixed part 2, 4, 8 is much greater in mass than the mobile part 5 which is also weighted down by useless loads in order to increase the energy recovered.

Since the energy recovered is directly a function of the worked mass, it is proposed to reverse the mechanical roles of the device and the counterweight. In contrast to current practice, the part previously fixed to the object in movement is freed, while the part previously in suspension is fixed to the object in movement.

The device 10 according to the invention, illustrated in FIG. 2B, therefore comprises a first part 12 and a second part 14 linked in a mobile way by first linking means 16. The second part 14 is also equipped with second means 18 which allow it to be connected in a rigid way to a support 3. According to the invention, the first part 12 is greater in mass than the second part 14.

In a preferred manner and as illustrated, the first part comprises a case 12 within which the second part 14 is located. In this configuration, the second linking means can be a mechanical shaft 18 that passes through the case 12. This rigid link can be created by any other means, and in particular by non-mechanical means like a magnetic or electrostatic connection. Depending in its use, it can be advantageous to position a sealing system 20 between the mobile part and the fixed shaft 18, such as a flexible membrane, in order, for example, to protect the interior of the device 10 and/or to guide the relative movement between first and second parts 12, 14.

According to the invention, the part 14 fixed to the support 3 can include only one of the active elements of the energy conversion system, while the mass in movement is no longer limited by the dimensions of the interior of the device 10. As a consequence, all additional mass on the mobile part 12 has a beneficial effect on the recoverable power, since the greater the mass in relative movement, the greater the recoverable power.

In a manner that is not exhaustive, the mass additional to that of the case 12 of the first part can be the electronic part of the system for the conversion and/or the exploitation of energy, with an energy storage unit serving as an energy buffer, its control electronics as the lid for the whole of the system, and even a complete sensor with its wireless communication system, such as a temperature sensor which, from time to time, would send out the temperature measured in the vicinity of the device 10 or any part of the latter. The mass in movement can thus increase by several orders of magnitude, thereby increasing, in the same proportion, the quantity of energy recoverable, with no change to or redimensioning of the energy converter 10, which retains the same dimensions.

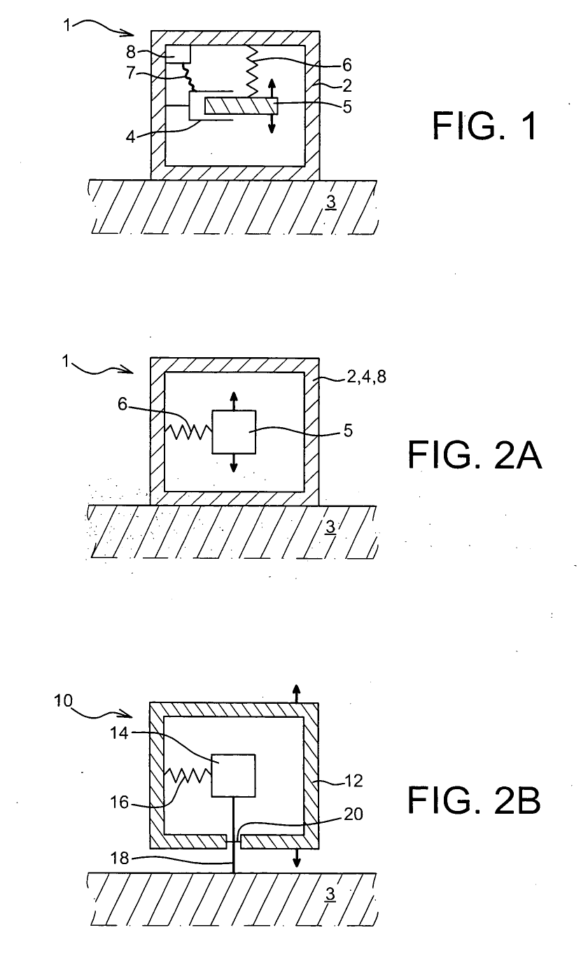

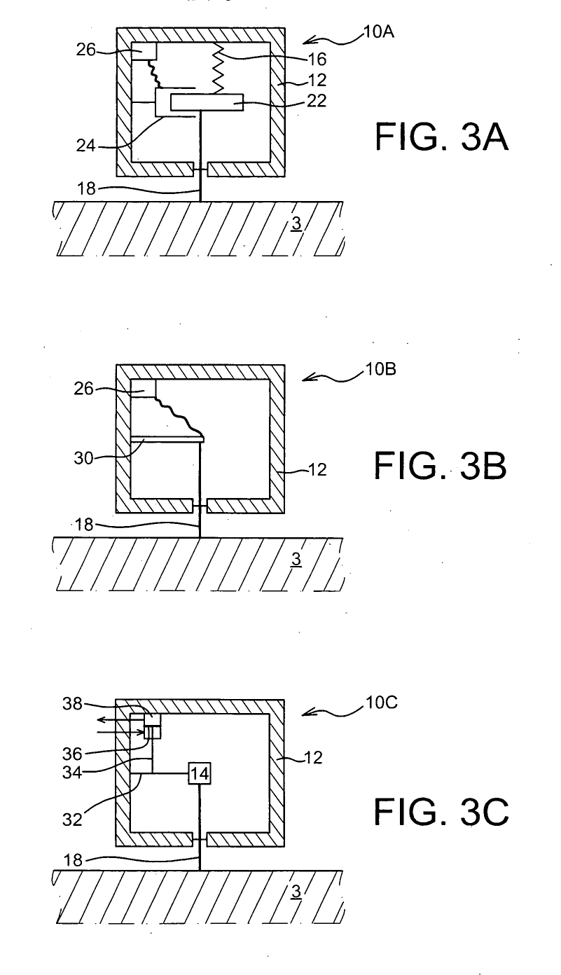

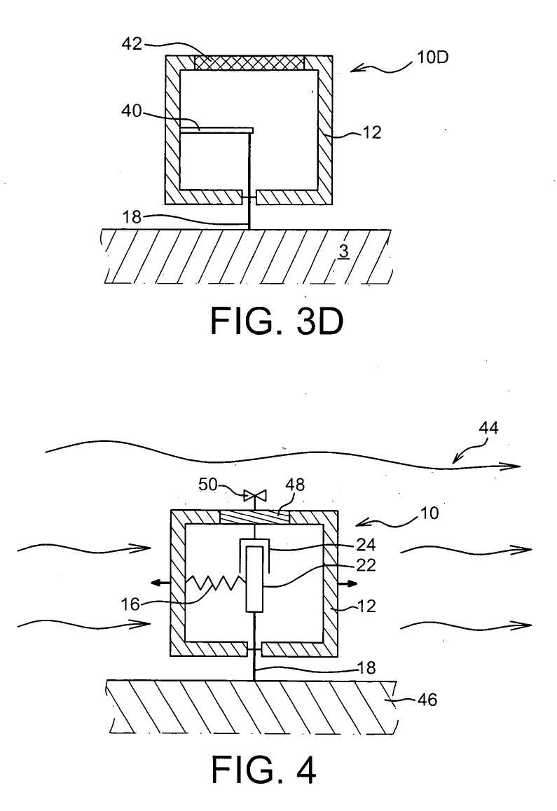

The device 10 according to the invention can concern all of the known principles for the conversion of mechanical energy. For example, as illustrated in FIG. 3A, the previous principle, illustrated in FIG. 1, can be used. The second fixed part of the device 10A thus comprises an electrode 22 forming an energy conversion system with another electrode 24 which is attached to the case 12. The case also comprises an electrical operating system 26 linked to the electrode 24. The first part 12, 24, 26 is connected in a mobile way to the second part 22, by a system acting as a spring 16 for example.

Another method to convert the mechanical energy of the support 3 into electrical energy concerns the piezoelectric principle illustrated in FIG. 3B. Here, the fixed part is composed of the end of the connection shaft 18, which is connected to the case 12 by means of an arm 30 composed, partially or totally, of piezoelectric material. The electrical energy produced by the relative movement between the case 12 and the shaft 18 is transmitted to an electrical operating system 26 via an electrical connector. It can be seen here that the difference of mass between the fixed part and the mobile part of the device 10B is optimal, and that the presence of ballast on the piezoelectric arm 30, which is obligatory in the case of a device functioning according to the known principle illustrated in FIG. 2A, is not necessary to recover a high electrical voltage.

For the two devices 10A and 10B, it is also possible not to use the electrical energy recovered immediately, but to store it, using a system such as a battery, a capacitor, etc. which can also be attached to the case 12 so as to still further increase the difference of mass between fixed and mobile parts.

The device according to the invention can also convert mechanical energy into mechanical energy, by pumping a fluid for example. In FIG. 3C, here again the second part is composed of a counterweight 14 attached to the support 3 by the rigid shaft 18. The first linking means between the fixed part 14 and the mobile part are composed of an articulated or flexible arm 32 which transmits the movement to a second arm 34 which is used to operate a piston 36 located, in the case represented, inside a chamber 38 with two admission valves. When the piston 36 rises, it closes the admission valve and compresses the fluid in the chamber 38, thus opening the extraction valve and ejecting the fluid. When the piston 36 drops, the pressure reduces in the chamber 38, thus opening the fluid admission valve, so that the fluid enters the chamber 38. Such a device 10C can therefore be used to pump a fluid, by virtue of the relative movements of a mobile part in relation to a support 3. Here again, the mobile part comprises, for example, the case 12, the articulation element 34, the piston 36, the chamber 38, etc. whose mass is greater than the part attached to the support 3 composed of the counterweight 14 and the shaft 18.

FIG. 3D illustrates a thermal energy conversion. The device 10D comprises a first mobile part 12 connected to a second fixed part 18 by a beam 40 which is subjected to flexing movements due to the movements between its two ends. Such flexing movements result in varying degrees of heating of the material constituting the beam. It is possible to detect this heating by means of an infrared camera for example. In this case, advantageously, portions of the case 12, or even a whole wall, are composed of material 42 that is transparent to infrared radiation. To increase the energy given off by the beam 40, it is possible to ballast its ends, in particular weighing down the case 12 using an energy storage system for example, or to choose the material of which it is made. In particular, a more rigid material dissipates more heat.

Although shown in operation by attachment to a mobile support 3 and also in an immobile environment, the devices according to the invention can also be used in a fluctuating environment, in particular comprising fluids in movement surrounding the case 12.

In fact, the mobile part, located outside of the device, is sensitive to possible fluctuations (laminar flows, turbulent flows, etc.) of the fluids surrounding it (air, water, etc.), which then allows the device to recover mechanical energy coming from the displacement of the fluids, either with or without movement of the support. Since the totality of the surface of the device 10 can then be used, the recoverable energy can increase significantly without adding fins or other elements that have no useful function on the outside of the device. For example, in the case where the device includes a system for the transmission of data to or from itself, the simple antenna used for this function can alone represent a sizeable surface area to capture forces coming from the fluids surrounding the system.

As illustrated in FIG. 4, for a device of the capacitive type, similar to that of FIG. 3A, the case 12 is placed in a liquid or gaseous fluid 44 in movement. The fixed part 18, 22 is attached to a support 46, which is also fixed in relation to the fluid 44. The mobile part includes an operating system for the electrical energy 48, which in the case illustrated is incorporated into the wall of the case 12. In addition, the operating system 48 also functions as a measuring station which emits the measurement, in electromagnetic form, to a remote base by means of a butterfly antenna 50. The movements of the fluid 44 surrounding the device 10 are transmitted to the mobile part of the variable capacitance via the butterfly antenna 50 used for the transmission of data, and which is attached to it.

The device according to the invention can therefore be used to recover energy of mechanical origin, with conversion into the wanted form of energy using any conversion principle. The devices illustrated are only examples of possible options. In addition, the device according to the invention can be used to recover the energy coming from the movements of its support and/or of the fluids surrounding it.

For example, on a silicon-based structure, it is possible to have the following:
For the conventional structure, the weight of the internal mobile part is 2.1 g, and this breaks down into 0.1 g of silicon and 2 g of tungsten, to increase the mass in movement. The weight of the external fixed part, including at least the case and the electronics, is 10 g.
For the structure implemented according to the invention, the weight of the fixed internal part is now longer only 0.1 g, since the addition of tungsten is no longer necessary. The mobile external part is comparable in weight and in constituents to that of the conventional structure.

As a consequence, the new structure is lighter by 2 g, while still allowing the recovery of at least 5 times as much energy, or the ratio of the weight of the mobile masses.

The principle of the recovery of energy of mechanical origin concerns the placement in suspension of the part with the greatest mass. Increasing the mass in movement is also possible without increasing the total mass of the recovery device of recovery or its volume, by placing in and on the part in suspension, all or part of the different elements of which the device is composed, with no addition of inactive masses which are of no use to its operation. Concerning capture of the forces in the fluids surrounding the device, in a similar manner, the capture area can be increased without the addition of useless elements of the fin type, by using the active constituents of the device.

It is intended that the elements and methods of implementations presented above can be combined in various ways, and that alternatives to the different components are also covered by the invention.

1-14. (canceled)

15. A device for recovering energy from an environment in movement, comprising:
a first and a second part movable in relation to each other;
first means for linking the first part to the second part in a mobile way; and
second means for linking the second part to a support in a rigid way,
wherein the first part has a mass that is greater than the mass of the second part, and the first part includes a case in which the second part is contained.

16. A device according to claim 15, wherein the second means includes a rigid link passing through the case.

17. A device according to claim 16, further comprising a sealing membrane between the case and the rigid link.

18. A device according to claim 15, further comprising an antenna located outside of the case.

19. A device according to claim 15, wherein the first means comprises an articulation system and the first part comprises a piston.

20. A device according to claim 15, wherein the first means comprises a beam whose deformation generates thermal energy.

21. A device according to claim 15, wherein each of the first and second parts includes an electrode, and the first means comprises an element acting as a spring.

22. A device according to claim 15, wherein the first means comprises at least partially a piezoelectric material.

23. A device according to claim 21, wherein the first part comprises an electronic element for operation of electrical energy obtained from conversion of the relative movement of the first and second parts.

24. A device according to claim 23, wherein the first part comprises means for storing the energy.

25. A device according to claim 15, wherein the first part comprises a sensor and/or an energy management system.

26. Use of a device according to claim 15, wherein the second means is connected to a mobile support.

27. Use of a device according to claim 15, wherein the device is located in a fluid in movement.

28. Use according to claim 27, in which the second means is connected to a support fixed to the fluid.
